(19) United States
(12) Patent Application Publication
(10) Pub. No.: US 2008/0309423 A1
(43) Pub. Date: Dec. 18, 2008

(54) VOLTAGE CONTROL OSCILLATOR AND OSCILLATION CONTROL SYSTEM

(75) Inventors: Nobuyuki ITOH, Tokyo (JP); Chiharu Nakajima, Tokyo (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 12/137,776

(22) Filed: Jun. 12, 2008

(30) Foreign Application Priority Data
Jun. 13, 2007 (JP) 2007-156085

(51) Int. Cl. H03B 5/12

(52) U.S. Cl. 331/117 FE

(57) ABSTRACT

A voltage control oscillator has a first MOS transistor having one end connected to a first potential; a second MOS transistor having one end connected to the first potential, a gate connected to an other end of the first MOS transistor, and an other end connected to a gate of the first MOS transistor; a first varactor having one end connected to the other end of the first MOS transistor, an other end connected to the other end of the second MOS transistor, and a capacitance changing with a first control voltage; a first inductor having one end connected to the one end of the first varactor; a second inductor having one end connected to the other end of the first varactor; a second varactor having one end connected to an other end of the first inductor, an other end connected to an other end of the second inductor, and a capacitance changing with a second control voltage; a third inductor connected between the one end of the second varactor and a second potential; and a fourth inductor connected between the other end of the second varactor and the second potential.

### CROSS-REFERENCE TO RELATED APPLICATION

This application is based upon and claims the benefit of priority from the prior Japanese Patent Application No. 2007-156085, filed on Jun. 13, 2007, the entire contents of which are incorporated herein by reference.

### BACKGROUND OF THE INVENTION

1. Field of the Invention

The present invention relates to a voltage control oscillator using a resonance phenomenon of an LC circuit, and an oscillation control system including the voltage control oscillator.

2. Background Art

In recent years, high-frequency integrated circuits have remarkably progressed and many radio circuits are realized on semiconductor integrated circuits using silicon.

Although voltage control oscillators have been conventionally regarded as being difficult to integrate, the integration has become a common practice.

On the other hand, as various radio standards have become prevalent, multiband and multisystem configurations have been recently demanded in some high-frequency integrated circuits. A typical example is software radios. Software radios are demanded to respond to various radio standards by means of software without changing hardware.

Generally, transmitter-receiver circuits capable of changing the frequency ranges and the operating currents have raised the possibility of the implementation of software radios.

However, the implementation of software radios has also raised various problems of the characteristics of voltage control oscillators.

One of the problems is the oscillation frequencies of voltage control oscillators. In order to respond to many radio standards, oscillation frequencies with an extremely wide variable range are demanded and have been realized.

However, not only the oscillation frequencies but also the gains are important to voltage control oscillators. When examining a local oscillator system using a phase locked loop (PLL), one of factors determining the spuriousness and lock-up time is the gain of a voltage control oscillator. In order to respond to various radio standards, a variable gain is an important factor to a voltage control oscillator.

Generally, an oscillation frequency “ω_{OSC}” of a voltage control oscillator is expressed by Formula (1). In Formula (1), Cv(V) is the capacitance of a varactor and L is the inductance of the voltage control oscillator.

$${ω}_{osc} = \frac{1}{\sqrt{{LC}_{V} ( V )}} \qquad ( 1 )$$

In a conventional voltage control oscillator, for example, as expressed in Formula (1), the oscillation frequency of the oscillator can be changed by making the capacitance “Cv(V)” variable (for example, see Japanese Patent Laid-Open No. 2005-269310).

The gain (K_{VCO}=dω_{OSC}/dV) of the voltage control oscillator is expressed by Formula (2).

$${K}_{VCO} = \frac{\partial ω osc}{\partial V} = - \frac{1}{2} ω {osc}^{3} L \frac{\partial {C}_{V} ( V )}{\partial V} \qquad ( 2 )$$

As expressed in Formula (2), in the conventional voltage control oscillator, the gain (=K_{VCO}) is substantially kept constant in a small range of oscillation frequencies and a small range of “dC_{V}/dv” and cannot be made variable.

### SUMMARY OF THE INVENTION

According to one aspect of the present invention, there is provided: a voltage control oscillator that outputs complementary differential signals from two output terminals respectively connected to both ends of varactors, comprising: a first MOS transistor having one end connected to a first potential; a second MOS transistor having one end connected to the first potential, a gate connected to an other end of the first MOS transistor, and an other end connected to a gate of the first MOS transistor; a first varactor having one end connected to the other end of the first MOS transistor, an other end connected to the other end of the second MOS transistor, and a capacitance changing with a first control voltage; a first inductor having one end connected to the one end of the first varactor; a second inductor having one end connected to the other end of the first varactor; a second varactor having one end connected to an other end of the first inductor, an other end connected to an other end of the second inductor, and a capacitance changing with a second control voltage; a third inductor connected between the one end of the second varactor and a second potential; and a fourth inductor connected between the other end of the second varactor and the second potential.

According to the other aspect of the present invention, there is provided: an system that controls oscillation, comprising: a voltage control oscillator that outputs complementary differential signals from two output terminals respectively connected to both ends of varactors, and comprises: a first MOS transistor having one end connected to potential a first potential; a second MOS transistor having one end connected to the first potential, a gate connected to an other end of the first MOS transistor, and an other end connected to a gate of the first MOS transistor; a first varactor having one end connected to the other end of the first MOS transistor, an other end connected to the other end of the second MOS transistor, and a capacitance changing with a first control voltage; a first inductor having one end connected to the one end of the first varactor; a second inductor having one end connected to the other end of the first varactor; a second varactor having one end connected to an other end of the first inductor, an other end connected to an other end of the second inductor, and a capacitance changing with a second control voltage; a third inductor connected between the one end of the second varactor and a second potential; and a fourth inductor connected between the other end of the second varactor and the second potential; an operating current supply circuit that supplies an operating current to the voltage control oscillator; and a control circuit that controls the voltage control oscillator by adjusting the first control voltage and the second control voltage.

### BRIEF DESCRIPTION OF THE DRAWINGS

FIG. 1 is a circuit diagram showing an example of a half circuit of a dispersed-type LC resonator circuit including two divided inductors and two divided capacitors;

FIG. 2 is a circuit diagram showing the configuration of the main part of the oscillation control system including the voltage control oscillator according to a first embodiment of the present invention;

FIG. 3 shows a layout including the inductors and varactors which compose the voltage control oscillator of FIG. 2;

FIG. 4 shows an example of the control voltage-oscillation frequency characteristic of the voltage control oscillator according to the first embodiment of the present invention;

FIG. 5 shows an example of the control voltage-oscillation frequency characteristic of the voltage control oscillator according to the first embodiment of the present invention;

FIG. 6 shows an example of the control voltage-oscillation frequency characteristic of the voltage control oscillator according to the first embodiment of the present invention; and

FIG. 7 shows an example of the control voltage-oscillation frequency characteristic of the voltage control oscillator according to the first embodiment of the present invention.

### DETAILED DESCRIPTION

In an embodiment of the present invention, an LC-dispersed voltage control oscillator including divided inductors and capacitors is used instead of an LC-centralized voltage control oscillator. In this voltage control oscillator, for example, a gain is made variable by fixing some of the varactors of the oscillator.

The embodiment of the present invention will be described below with reference to the accompanying drawings.

### First Embodiment

First, the following will examine the characteristics of a dispersed-type LC oscillator applied to a voltage control oscillator of a first embodiment. The dispersed-type LC oscillator has a dispersed-type LC oscillator circuit including divided inductors and capacitors.

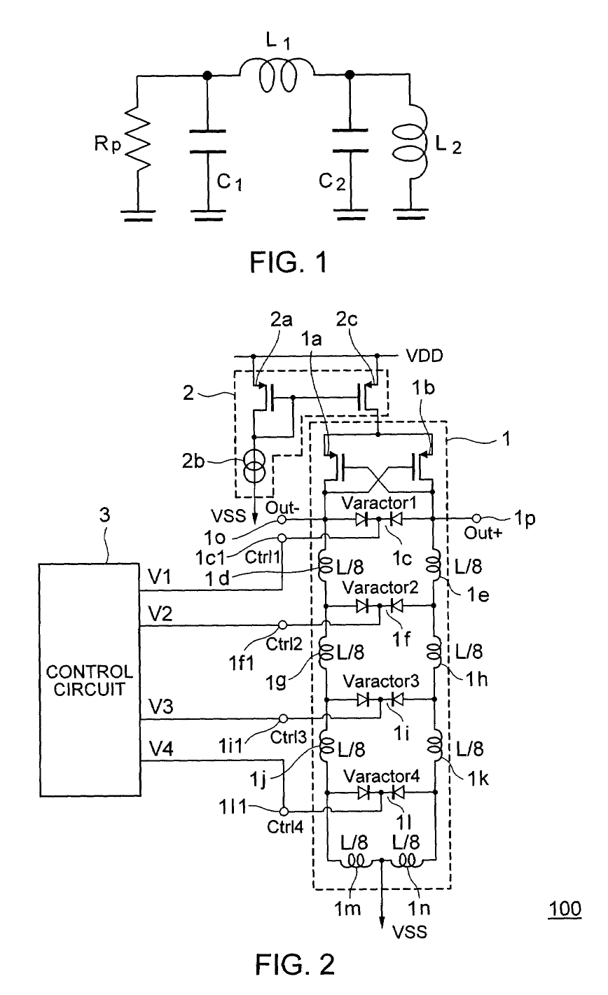

FIG. 1 is a circuit diagram showing an example of a half circuit of a dispersed-type LC resonator circuit including two divided inductors and two divided capacitors.

The dispersed-type LC resonator circuit shown in FIG. 1 has an impedance “Zₜₒₜ” expressed by Formula (3).

$${Z}_{tot} = \frac{{sR}_{p} \{ ( {L}_{1} + {L}_{2} ) + {s}^{2} {L}_{1} {L}_{2} {C}_{2} \}}{\begin{matrix}{R}_{p} \{ 1 + {s}^{2} {L}_{2} {C}_{2} + {s}^{2} ( {L}_{1} {C}_{1} + {L}_{2} {C}_{1} + {L}_{2} {C}_{2} ) + {s}^{4} {L}_{1} {L}_{2} {C}_{1} {C}_{2} \} + \\ s \{ ( {L}_{1} + {L}_{2} ) + {s}^{2} {L}_{1} {L}_{2} {C}_{2} \}\end{matrix}} \qquad ( 3 )$$

Further, the impedance “Zₜₒₜ” has a real part “Z_{tot,real}” expressed by Formula (4).

$${Z}_{tot , real} = \frac{- {s}^{2} {R}_{p} {\{ ( {L}_{1} + {L}_{2} ) + {s}^{2} {L}_{1} {L}_{2} {C}_{2} \}}^{2}}{\begin{matrix}{R}_{p}^{2} {\{ 1 + {s}^{2} {L}_{2} {C}_{2} + {s}^{2} ( {L}_{1} {C}_{1} + {L}_{2} {C}_{1} + {L}_{2} {C}_{2} ) + {s}^{4} {L}_{1} {L}_{2} {C}_{1} {C}_{2} \}}^{2} - \\ {s}^{2} {\{ ( {L}_{1} + {L}_{2} ) + {s}^{2} {L}_{1} {L}_{2} {C}_{2} \}}^{2}\end{matrix}} \qquad ( 4 )$$

Moreover, the impedance “Zₜₒₜ” has an imaginary part “Z_{tot,img}” expressed by Formula (5).

$${Z}_{tot , img} = \frac{\begin{matrix}- s \{ ( {L}_{1} + {L}_{2} ) + {s}^{2} {L}_{1} {L}_{2} {C}_{2} \} \\ \{ 1 + {s}^{2} ( {L}_{1} {C}_{1} + {L}_{2} {C}_{1} + {L}_{2} {C}_{2} ) + {s}^{4} {L}_{1} {L}_{2} {C}_{1} {C}_{2} \}\end{matrix}}{\begin{matrix}\begin{matrix}{R}_{p}^{2} \{ 1 + {s}^{2} {L}_{2} {C}_{2} + \\ {{s}^{2} ( {L}_{1} {C}_{1} + {s}^{2} ( {L}_{1} {C}_{1} + {L}_{2} {C}_{1} + {L}_{2} {C}_{2} ) + {s}^{4} {L}_{1} {L}_{2} {C}_{1} {C}_{2} \}}^{2} -\end{matrix} \\ {s}^{2} {\{ ( {L}_{1} + {L}_{2} ) + {s}^{2} {L}_{1} {L}_{2} {C}_{2} \}}^{2}\end{matrix}} {R}_{p}^{2} \qquad ( 5 )$$

In order to establish the resonator circuit, the resonator circuit requires a resonance point. In other words, the imaginary part “Z_{tot,img}”=0 and the real part >0 have to be satisfied. Therefore, Formula (5) proves that at least Formula (6) or (7) has to be established to satisfy the imaginary part “Z_{tot,img}”=0.

(L₁+L₂)+s²L₁L₂C₂=0 (6)

1+s²(L₁C₁+L₂C₁+L₂C₂)+s⁴L₁L₂C₁C₂=0 (7)

Based on Formula (6), Formula (8) is established as below:

$${ω}_{0} = \sqrt{\frac{{L}_{1} + {L}_{2}}{{L}_{1} {L}_{2} {C}_{2}}} \qquad ( 8 )$$

where ω₀ is a resonance frequency.

However, in this case, the impedance has the real part “Z_{tot,real}”=0 expressed by Formula (4). Thus the dispersed-type LC resonator circuit does not operate as a resonator.

On the other hand, Formula (9) is established based on Formula (7).

$${ω}_{0}^{2} = \frac{\begin{matrix}( {L}_{1} {C}_{1} + {L}_{2} {C}_{1} + {L}_{2} {C}_{2} ) \underline{+} \\ \sqrt{{( {L}_{1} {C}_{1} + {L}_{2} {C}_{1} + {L}_{2} {C}_{2} )}^{2} - 4 {L}_{1} {L}_{2} {C}_{1} {C}_{2}}\end{matrix}}{2 {L}_{1} {L}_{2} {C}_{1} {C}_{2}} \qquad ( 9 )$$

In this case, the impedance has the real part “Z_{tot,real}”>0 expressed by Formula (4). Thus the dispersed-type LC resonator circuit operates as a resonator.

In this case, Formula (10) and Formula (11) are established as below. In Formula (10) and Formula (11), L is the total inductance of the dispersed-type LC resonator circuit and C is the total capacitance of the resonator.

$$\begin{matrix}{L}_{1} = {L}_{2} = \frac{L}{4} & ( 10 ) \\ {C}_{1} = {C}_{2} = \frac{C}{4} & ( 11 )\end{matrix}$$

Therefore, Formula (12) is established based on Formulas (9), (10), and (11).

$${ω}_{0} = \frac{\sqrt{6 \underline{+} 2 \sqrt{5}}}{\sqrt{LC}} \approx \frac{1.24}{\sqrt{LC}} , \frac{3.24}{\sqrt{LC}} \qquad ( 12 )$$

In this case, for example, a centralized-type LC resonator circuit of a centralized-type LC oscillator including an undivided inductor and capacitor has a resonance frequency “ω₀” expressed by Formula (13).

$${ω}_{0} = \frac{1}{\sqrt{LC}} \qquad ( 13 )$$

Therefore, by using a dispersed-type LC oscillator as a voltage control oscillator, for example, an oscillation frequency 1.24 or 3.24 times as high as the oscillation frequency “ω₀” can be obtained with a combination of L and C as expressed in Formula (12).

Further, during the resonance of the dispersed-type LC resonator circuit, an impedance has a real part “Z_{tot,real}” expressed by Formula (14).

Z_{tot,real}=Rp (14)

Thus an oscillation amplitude “V_{osc}” of the voltage control oscillator can be expressed by Formula (15). In Formula (15), “I” is an operating current for operating the voltage control oscillator.

$${V}_{osc} = \frac{2}{π} I \cdot {Z}_{tot , real} \qquad ( 15 )$$

Further, it is possible to increase the real part (=Rp) of the impedance of the dispersed-type LC resonator circuit, thereby increasing the oscillation amplitude of the dispersed-type LC oscillator (voltage control oscillator) as expressed in Formula (15). Alternatively, it is possible to reduce the bias current of the dispersed-type LC oscillator even at the same oscillation amplitude.

In the dispersed-type LC resonator circuit, C₁ and C₂ can be separately controlled, so that the gain of the voltage control oscillator can be made variable.

The following will describe an oscillation control system including the voltage control oscillator having the aforementioned characteristics according to the first embodiment.

In the following explanation, a first potential will be referred to as a power supply potential VDD and a second potential will be referred to as a ground potential VSS. The second potential may be referred to as the power supply potential VDD, the first potential may be referred to as the ground potential VSS, and the polarity of the circuit may be changed.

FIG. 2 is a circuit diagram showing the configuration of the main part of the oscillation control system including the voltage control oscillator according to the first embodiment of the present invention.

As shown in FIG. 2, an oscillation control system 100 includes a voltage control oscillator 1 which is a dispersed-type LC oscillator, an operating current supply circuit 2 for supplying an operating current to the voltage control oscillator 1, and a control circuit 3 for controlling the voltage control oscillator 1 by adjusting a control voltage.

The voltage control oscillator 1 includes a first MOS transistor 1a, a second MOS transistor 1b, a first varactor 1c, a first inductor 1d, a second inductor 1e, a second varactor 1f, a third inductor 1g, and a fourth inductor 1h.

Further, the voltage control oscillator 1 includes a third varactor 1i, a fifth inductor 1j, a sixth inductor 1k, a fourth varactor 1l, a seventh inductor 1m, and an eighth inductor in.

The first MOS transistor 1a is, for example, a p-type MOS transistor. The first MOS transistor 1a has one end (source) connected to the first potential (power supply potential VDD) via the operating current supply circuit 2.

The second MOS transistor 1b is a p-type MOS transistor having the same conductivity type as the first MOS transistor 1a. The second MOS transistor 1b has one end (source) connected to the power supply potential VDD, the gate connected to the other end (drain) of the first MOS transistor 1a, and the other end (drain) connected to the gate of the first MOS transistor 1a.

The first varactor 1c has one end connected to the other end (drain) of the first MOS transistor 1a and the other end connected to the other end (drain) of the second MOS transistor 1b. The capacitance of the first varactor 1c changes with a first control voltage V1 inputted through a first control terminal 1c1. The first inductor 1d has one end connected to the one end of the first varactor 1c. The second inductor 1e has one end connected to the other end of the first varactor 1c. As shown in FIG. 2, for example, the varactors are each made up of two diodes having the cathodes commonly connected to the control terminal.

The second varactor 1f has one end connected to the other end of the first inductor 1d and the other end connected to the other end of the second inductor 1e. The capacitance of the second varactor 1f changes with a second control voltage V2 inputted through a second control terminal 1e1. The third inductor 1g has one end connected to the one end of the second varactor 1f. The fourth inductor 1h has one end connected to the other end of the second varactor 1f.

The third varactor 1i has one end connected to the other end of the third inductor 1g and the other end connected to the other end of the fourth inductor 1h. The capacitance of the third varactor 1i changes with a third control voltage V3 inputted through a third control terminal 1i1. The fifth inductor 1j has one end connected to the one end of the third varactor 1i. The sixth inductor 1k has one end connected to the other end of the third varactor 1i.

The fourth varactor 1l has one end connected to the other end of the fifth inductor 1j and the other end connected to the other end of the sixth inductor 1k. The capacitance of the fourth varactor 1i changes with a fourth control voltage V4 inputted through a fourth control terminal 1l1. The seventh inductor 1m is connected between the one end of the fourth varactor 1l and the second potential (ground potential VSS). The eighth inductor in is connected between the other end of the fourth varactor 1l and the ground potential VSS.

In the present embodiment, for example, the first to eighth inductors 1d, 1e, 1g, 1h, 1j, 1k, 1m and 1n have the same inductance (L/8). Further, for example, the first to fourth varactors 1c, 1f, 1i, and 1l have the same capacitance.

With this configuration, the voltage control oscillator 1 outputs complementary differential signals from first and second output terminals 1o and 1p connected to both ends of the varactors.

In the voltage control oscillator 1, the capacitance values of the first to fourth varactors 1c, 1f, 1i, and 1l are changed by adjusting the first to fourth control voltages V1 to V4, so that the gain is changed.

One of the first to fourth control voltages V1 to V4 may be a fixed voltage. For example, the fixed voltage is a power supply voltage or a ground voltage or the like.

Moreover, all the inductors do not always have to have the same inductance. In other words, in order to output the complementary differential signals from the first and second output terminals 1o and 1p, the same inductance is necessary only for each of the pairs of the first inductor 1d and the second inductor 1e, the third inductor 1g and the fourth inductor 1h, the fifth inductor 1j and the sixth inductor 1k, and the seventh inductor 1m and the eighth inductor 1n.

As shown in FIG. 2, the operating current supply circuit 2 includes, for example, a third MOS transistor 2a, a current source 2b, and a fourth MOS transistor 2c.

The third MOS transistor 2a is a p-type MOS transistor having one end (source) connected to the power supply potential VDD and the gate connected to the drain. In other words, the third MOS transistor 2a is diode-connected.

The current source 2b is connected between the drain of the third MOS transistor 2a and the ground potential VSS.

The fourth MOS transistor 2c is a p-type MOS transistor having one end (source) connected to the power supply potential VDD and the gate connected to the gate of the first transistor.

With this configuration, the third MOS transistor 2a and the fourth MOS transistor 2c compose a current mirror circuit. Therefore, a current mirrored from a current passing through the third MOS transistor 2a passes through the fourth MOS transistor 2c. The mirrored current is supplied as an operating current from the drain of the fourth MOS transistor 2c to the voltage control oscillator 1.

The control circuit 3 inputs the first to fourth control voltages V1 to V4 to the voltage control oscillator 1 through the first to fourth control terminals 1c1, 1f1, 1i1, and 1l1 and controls the oscillation frequency and gain of the voltage control oscillator 1.

The control circuit 3 adjusts the control voltages to respond to various radio standards, so that the gain of the voltage control oscillator is made variable. As described above, for example, the control voltages are fixed voltages including the power supply voltage and the ground voltage.

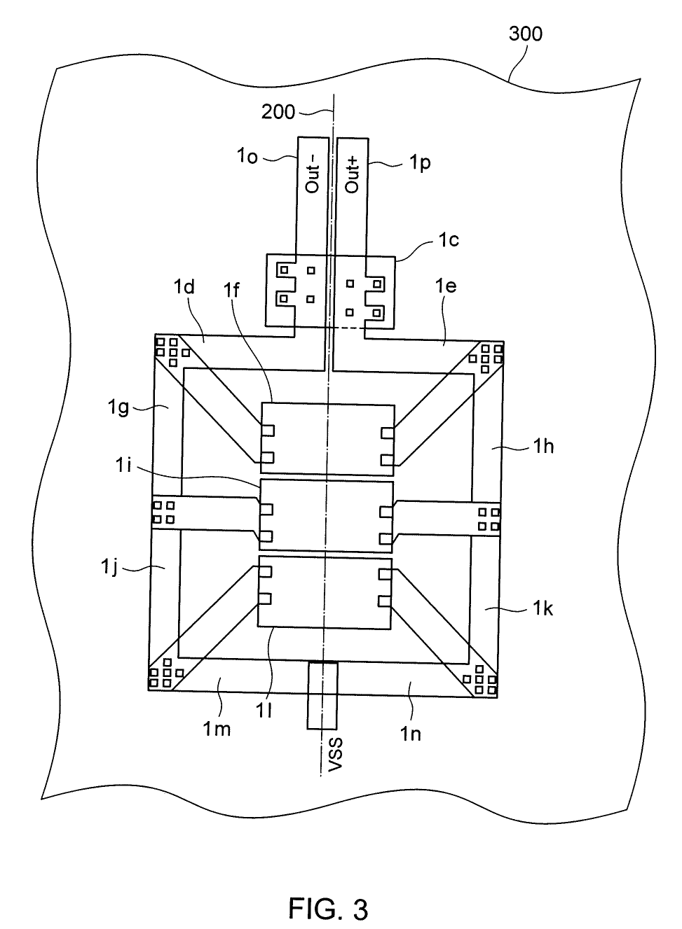

FIG. 3 shows a layout including the inductors and varactors which compose the voltage control oscillator of FIG. 2. In FIG. 3, other configurations including the MOS transistors are omitted for simplicity.

As shown in FIG. 3, the first inductor 1d and the second inductor 1e are disposed on a semiconductor substrate 300 so as to be symmetric with respect to an axis 200. Further, the third inductor 1g and the fourth inductor 1h are disposed on the semiconductor substrate 300 so as to be symmetric with respect to the axis 200. Moreover, the fifth inductor 1j and the sixth inductor 1k are disposed on the semiconductor substrate 300 so as to be symmetric with respect to the axis 200. Further, the seventh inductor 1m and the eighth inductor 1n are disposed on the semiconductor substrate 300 so as to be symmetric with respect to the axis 200.

Elements composing the first varactor 1c are disposed on the semiconductor substrate 300 so as to be substantially symmetric with respect to the axis 200. Further, elements composing the second varactor 1f are disposed on the semiconductor substrate 300 so as to be symmetric with respect to the axis 200. Moreover, elements composing the third varactor 1i are disposed on the semiconductor substrate 300 so as to be symmetric with respect to the axis 200. Further, elements composing the fourth varactor 1l are disposed on the semiconductor substrate 300 so as to be symmetric with respect to the axis 200. In other words, the axis 200 is a line indicating line symmetry.

In other words, FIG. 3 shows a layout in which the first to fourth varactors 1c, 1f, 1i, and 1l are symmetric to the inductors. Thus a symmetric layout configuration is obtained.

Further, as shown in FIG. 3, the varactors and the inductors may be radially disposed with respect to the axis 200. This layout can reduce the influence of parasitic resistance while avoiding the influence of overcurrent.

The following will describe the characteristics of the voltage control oscillator configured thus according to the first embodiment and the characteristics of a conventional voltage control oscillator (centralized-type LC oscillator).

As an example, the following will describe simulation results obtained when one or two of the first to fourth control voltages is made variable so as to continuously change, and the other control voltages are set at a first fixed voltage or a second fixed voltage lower than the first fixed voltage.

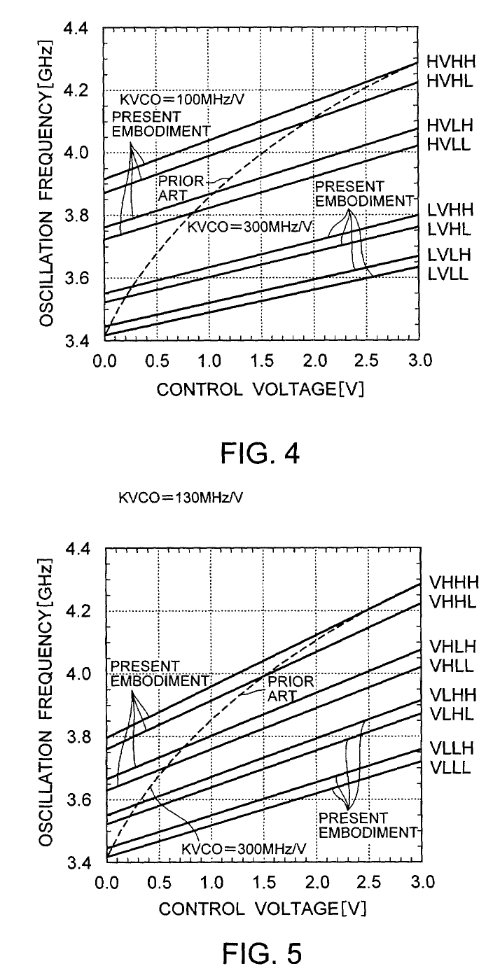

FIGS. 4 to 7 show an example of the control voltage-oscillation frequency characteristics of the voltage control oscillator according to the first embodiment of the present invention.

In FIGS. 4 to 7, the variable voltage is represented as “V” and the other voltages are represented as the first fixed voltage “H” or the second fixed voltage “L” lower than the first fixed voltage. In this case, for example, the first fixed voltage is the power supply voltage and the second fixed voltage is the ground voltage.

As shown in FIG. 4, the voltage control oscillator of the prior art has a gain (KVCO) of, for example, about 300 MHz/V (also in FIGS. 5 to 7).

In the voltage control oscillator of the present embodiment, as shown in FIG. 4, the first control voltage, the second control voltage, the third control voltage, and the fourth control voltage are adjusted to “D”, “V”, “D” and “D” (“D” is the first fixed voltage “H” or the second fixed voltage “L”). Thus the gain (KVCO) can be set at about 100 MHz/V. The oscillation frequency can be changed by adjusting the fixed voltages.

Further, as shown in FIG. 5, in the voltage control oscillator of the present embodiment, the first control voltage, the second control voltage, the third control voltage, and the fourth control voltage are adjusted to “V”, “D”, “D” and “D”. Thus the gain (KVCO) can be set at about 130 MHz/V. As described above, the oscillation frequency can be changed by adjusting the fixed voltages.

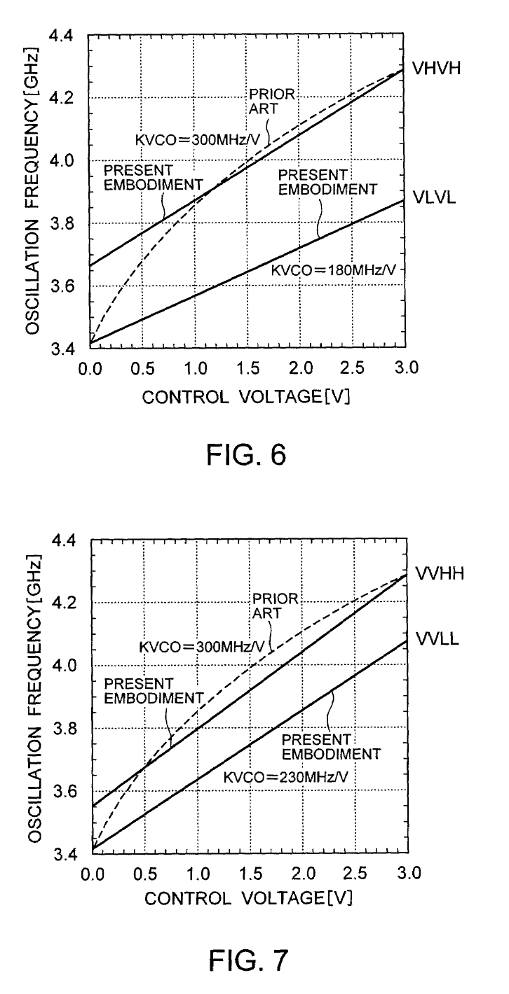

Moreover, as shown in FIG. 6, in the voltage control oscillator of the present embodiment, the first control voltage, the second control voltage, the third control voltage, and the fourth control voltage are adjusted to “V”, “D”, “V” and “D”. Thus the gain (KVCO) can be set at about 180 MHz/V. As described above, the oscillation frequency can be changed by adjusting the fixed voltages. In FIG. 6, only the combination of “V”, “L”, “V” and “L” and the combination of “V”, “H”, “V” and “H” are shown for simplicity.

Further, as shown in FIG. 7, in the voltage control oscillator of the present embodiment, the first control voltage, the second control voltage, the third control voltage, and the fourth control voltage are adjusted to “V”, “V”, “D” and “D”. Thus the gain (KVCO) can be set at about 230 MHz/V. As described above, the oscillation frequency can be changed by adjusting the fixed voltages. In FIG. 7, only the combination of “V”, “V”, “L” and “L” and the combination of “V”, “V”, “H” and “H” are shown for simplicity.

As described above, the gain of the voltage control oscillator can be made variable by adjusting the first to fourth control voltages.

In addition to the combinations of the control voltages shown in FIGS. 4 to 7, three of the first to fourth control voltages or all the control voltages may be the variable voltage “V” which continuously changes.

The variable voltage “V” and first and second fixed voltages “H” and “L” applied to the first to fourth control voltages V1 to V4 are adjusted so as to respond to radio standards.

As described above, the voltage control oscillator of the present embodiment can change the gain so as to respond to, for example, various radio standards.

In the embodiment, as an example, the four varactors and the eight inductors are provided. The fourth varactor and the seventh and eighth inductors may be omitted to reduce the number of varactors to three and the number of inductors to six. Further, the third varactor and the fifth and sixth inductors may be omitted to reduce the number of varactors to two and the number of inductors to four.

The operation and effect of the present invention can be obtained also when a varactor and an inductor are added to the voltage control oscillator of the present embodiment.

What is claimed is:

1. A voltage control oscillator that outputs complementary differential signals from two output terminals respectively connected to both ends of varactors, comprising:
a first MOS transistor having one end connected to a first potential;
a second MOS transistor having one end connected to the first potential, a gate connected to an other end of the first MOS transistor, and an other end connected to a gate of the first MOS transistor;
a first varactor having one end connected to the other end of the first MOS transistor, an other end connected to the other end of the second MOS transistor, and a capacitance changing with a first control voltage;
a first inductor having one end connected to the one end of the first varactor;
a second inductor having one end connected to the other end of the first varactor;
a second varactor having one end connected to an other end of the first inductor, an other end connected to an other end of the second inductor, and a capacitance changing with a second control voltage;
a third inductor connected between the one end of the second varactor and a second potential; and
a fourth inductor connected between the other end of the second varactor and the second potential.

2. The voltage control oscillator according to claim 1, wherein the first control voltage is a fixed voltage.

3. The voltage control oscillator according to claim 1, wherein the second control voltage is a fixed voltage.

4. The voltage control oscillator according to claim 2, wherein the fixed voltage is a power supply voltage or a ground voltage.

5. The voltage control oscillator according to claim 3, wherein the fixed voltage is a power supply voltage or a ground voltage.

6. The voltage control oscillator according to claim 1, wherein the first inductor and the second inductor are disposed on a semiconductor substrate so as to be symmetric with respect to an axis,
the third inductor and the fourth inductor are disposed on the semiconductor substrate so as to be symmetric with respect to the axis,
the first varactor is disposed on the semiconductor substrate so as to be symmetric with respect to the axis, and the second varactor is disposed on the semiconductor substrate so as to be symmetric with respect to the axis.

7. The voltage control oscillator according to claim 2, wherein the first inductor and the second inductor are disposed on a semiconductor substrate so as to be symmetric with respect to an axis,
the third inductor and the fourth inductor are disposed on the semiconductor substrate so as to be symmetric with respect to the axis,
the first varactor is disposed on the semiconductor substrate so as to be symmetric with respect to the axis, and
the second varactor is disposed on the semiconductor substrate so as to be symmetric with respect to the axis.

8. The voltage control oscillator according to claim 3, wherein the first inductor and the second inductor are disposed on a semiconductor substrate so as to be symmetric with respect to an axis,
the third inductor and the fourth inductor are disposed on the semiconductor substrate so as to be symmetric with respect to the axis,
the first varactor is disposed on the semiconductor substrate so as to be symmetric with respect to the axis, and
the second varactor is disposed on the semiconductor substrate so as to be symmetric with respect to the axis.

9. The voltage control oscillator according to claim 4, wherein the first inductor and the second inductor are disposed on a semiconductor substrate so as to be symmetric with respect to an axis,
the third inductor and the fourth inductor are disposed on the semiconductor substrate so as to be symmetric with respect to the axis,
the first varactor is disposed on the semiconductor substrate so as to be symmetric with respect to the axis, and
the second varactor is disposed on the semiconductor substrate so as to be symmetric with respect to the axis.

10. The voltage control oscillator according to claim 5, wherein the first inductor and the second inductor are disposed on a semiconductor substrate so as to be symmetric with respect to an axis,
the third inductor and the fourth inductor are disposed on the semiconductor substrate so as to be symmetric with respect to the axis,
the first varactor is disposed on the semiconductor substrate so as to be symmetric with respect to the axis, and
the second varactor is disposed on the semiconductor substrate so as to be symmetric with respect to the axis.

11. An system that controls oscillation, comprising:
a voltage control oscillator that outputs complementary differential signals from two output terminals respectively connected to both ends of varactors, and comprises: a first MOS transistor having one end connected to potential a first potential; a second MOS transistor having one end connected to the first potential, a gate connected to an other end of the first MOS transistor, and an other end connected to a gate of the first MOS transistor; a first varactor having one end connected to the other end of the first MOS transistor, an other end connected to the other end of the second MOS transistor, and a capacitance changing with a first control voltage; a first inductor having one end connected to the one end of the first varactor; a second inductor having one end connected to the other end of the first varactor; a second varactor having one end connected to an other end of the first inductor, an other end connected to an other end of the second inductor, and a capacitance changing with a second control voltage; a third inductor connected between the one end of the second varactor and a second potential; and a fourth inductor connected between the other end of the second varactor and the second potential;
an operating current supply circuit that supplies an operating current to the voltage control oscillator; and
a control circuit that controls the voltage control oscillator by adjusting the first control voltage and the second control voltage.

12. The system according to claim 11, wherein the first control voltage is a fixed voltage.

13. The system according to claim 11, wherein the second control voltage is a fixed voltage.

14. The system according to claim 12, wherein the fixed voltage is a power supply voltage or a ground voltage.

15. The system according to claim 13, wherein the fixed voltage is a power supply voltage or a ground voltage.

16. The system according to claim 11, wherein the first inductor and the second inductor are disposed on a semiconductor substrate so as to be symmetric with respect to an axis,
the third inductor and the fourth inductor are disposed on the semiconductor substrate so as to be symmetric with respect to the axis,
the first varactor is disposed on the semiconductor substrate so as to be symmetric with respect to the axis, and
the second varactor is disposed on the semiconductor substrate so as to be symmetric with respect to the axis.

17. The system according to claim 12, wherein the first inductor and the second inductor are disposed on a semiconductor substrate so as to be symmetric with respect to an axis,
the third inductor and the fourth inductor are disposed on the semiconductor substrate so as to be symmetric with respect to the axis,
the first varactor is disposed on the semiconductor substrate so as to be symmetric with respect to the axis, and
the second varactor is disposed on the semiconductor substrate so as to be symmetric with respect to the axis.

18. The system according to claim 13, wherein the first inductor and the second inductor are disposed on a semiconductor substrate so as to be symmetric with respect to an axis,
the third inductor and the fourth inductor are disposed on the semiconductor substrate so as to be symmetric with respect to the axis,
the first varactor is disposed on the semiconductor substrate so as to be symmetric with respect to the axis, and
the second varactor is disposed on the semiconductor substrate so as to be symmetric with respect to the axis.

19. The system according to claim 14, wherein the first inductor and the second inductor are disposed on a semiconductor substrate so as to be symmetric with respect to an axis,
the third inductor and the fourth inductor are disposed on the semiconductor substrate so as to be symmetric with respect to the axis,
the first varactor is disposed on the semiconductor substrate so as to be symmetric with respect to the axis, and
the second varactor is disposed on the semiconductor substrate so as to be symmetric with respect to the axis.

20. The system according to claim 15, wherein the first inductor and the second inductor are disposed on a semiconductor substrate so as to be symmetric with respect to an axis,
the third inductor and the fourth inductor are disposed on the semiconductor substrate so as to be symmetric with respect to the axis,
the first varactor is disposed on the semiconductor substrate so as to be symmetric with respect to the axis, and
the second varactor is disposed on the semiconductor substrate so as to be symmetric with respect to the axis.
